(19) United States
(12) Patent Application Publication
(10) Pub. No.: US 2011/0050310 A1
(43) Pub. Date: Mar. 3, 2011

(54) LEVEL SHIFTER CIRCUIT

(75) Inventor: Maurits M. N. Storms, Best (NL)

(73) Assignee: NXP B.V., Eindhoven (NL)

(21) Appl. No.: 12/671,742

(22) PCT Filed: Aug. 8, 2008
(86) PCT No.: PCT/IB08/53193

§ 371 Date: Feb. 2, 2010

(30) Foreign Application Priority Data
Aug. 13, 2007 (EP) 07114251.7

(51) Int. Cl. H03K 3/356

(52) U.S. Cl. 327/208

(57) ABSTRACT

The present invention relates to a level shifter circuit (20) for transistors requiring high voltage, such as nonvolatile memories. In the circuit configuration, the drain- to-source voltage across the NMOS transistors (Q1, Q4) can be substantially equal to the power supply voltage (VPP) according to the input voltage level at the complementary input terminals (IN, INB). For alleviating such a voltage stress, the source potential of each NMOS transistor is increased according to the input voltage level. Thus, the source of the transistor at the OUT side is biased by the input signal at the input terminal (IN) and the source of the transistor at the IN side is biased by the complementary input signal at the corresponding terminal (INB). Hot-carrier degradation and leakage of the load current flowing through from the power supply voltage (VPP) to the reference voltage (VSS) can be then reduced.

### FIELD OF THE INVENTION

The present invention relates to the field of level shifter circuits, and more specifically to high-voltage level shifter transistors for reducing voltage stress and leakage.

### BACKGROUND OF THE INVENTION

Level shifters have been used in many applications in which a transition from a voltage level to a higher voltage level is needed. For example, an integrated circuit may be required to drive a digital output pin with a logic one voltage level higher than the logic one voltage level used by the internal logic of the integrated circuit. In the alternative, level shifters may be used to transition from a voltage level to a lower voltage level.

For applications in nonvolatile semiconductor memory transistors such as EEPROM (Electrically-Erasable Programmable Read-Only Memory), flash EEPROM, NOVRAM (Non Volatile Random Access Memory), OTP (One-Time Programmable) or MTP (Multiple-Time Programmable) nonvolatile memory, it is conventional to use level shifters for driving the word lines connected to the control gates of memory cell transistors in a cell array. Indeed, in order to write data in such memory cell transistors, it is necessary to supply them with a write-in voltage that is higher than the read-out voltage. For example, in a data read mode, a read-out voltage (e.g. within a range of 1.8 to 5.5 V) of usually less than or equal to the digital supply voltage VDD is supplied to a control gate of the memory cell transistor. In a programming mode, a write-in voltage of 10 V or higher (e.g. 12.5 V) is supplied to the control gate of the memory cell transistor. Such high voltages for programming operations are usually generated on chip by voltage multiplier circuits such as charge pumps. Because the on-chip charge pumps are costly in die area and power consumption, these level shifters are commonly used for both programming operations, namely not only during writes but also during reads. In such a case, the output level supply voltage VPP tied to the level shifter is simply reduced during read operations.

FIG. 1 shows a circuit diagram illustrating a 4-transistor level shifter according to the prior art. The level shifter comprises two N-type transistors Q1 and Q4 provided at the side of a reference voltage VSS, e.g. grounded voltage, and receiving, through the use of an inverter (not shown), complementary input signals from an input terminal IN and an input terminal INB, respectively, (both inputs can be supplied by a row decoder for example), and two P-type transistors Q2 and Q3 provided at the side of a power supply voltage, e.g. programming voltage VPP, generated by an on-chip charge pump for example. The cross-coupled transistors Q2 and Q3 constitute a flip-flop. The gate terminal of each transistor is connected to the drain terminal of the other at a series-connection node N2 of the transistors Q3 and Q4 and at a series-connection node N1 of the transistors Q1 and Q2, respectively. The substrate and source terminal of each of them are connected to the power supply voltage VPP. Each of both transistors Q1 and Q4 has its substrate and source terminal connected to the reference voltage VSS and its drain terminal connected to the nodes N1 and N2, respectively. The node N2 is connected to an output terminal OUT for outputting an shifted-level output signal.

In a stationary state, when a signal is inputted at the input terminal IN with a high level, e.g. VCC, which is lower than the high level of the power supply voltage VPP, the transistor Q1 is turned ON and the transistor Q4 is turned OFF. In this case, the transistor Q3 is turned ON and the transistor Q2 is then turned OFF. The node N1 is pulled-down by the transistor Q1 at a low level provided by the reference voltage VSS, and the node N2 connected to the output terminal OUT is pulled-up by the transistor Q3 at a high level provided by the power supply voltage VPP. Thus, the drain-to-source voltage across the transistors Q2 and Q4 is substantially equal to the power supply voltage VPP, which results in high electric field and enhances hot-carrier degradation and the leakage of the load current flowing through from the power supply voltage VPP to the reference supply voltage VSS. Therefore, the reliability of such a conventional circuit can be affected.

In an alternative stationary state, when a signal is inputted at the input terminal IN with a low level, e.g. VSS, the transistor Q1 is turned OFF and the transistor Q4 is turned ON. In this case, the transistor Q2 is turned ON and the transistor Q3 is turned OFF. The node N1 is at a high level provided by the power supply voltage VPP, and the node N2 connected to the output terminal OUT is at a low level provided by the reference voltage VSS. Thus, the drain-to-source voltage across the transistors Q1 and Q3 is substantially equal to the power supply voltage VPP, which results in high electric field and enhances hot-carrier degradation and the leakage of the load current flowing through from the power supply voltage VPP to the reference supply voltage VSS. Therefore, the reliability of such a conventional circuit can be affected.

Voltage level shifters using stacked transistors between drain and source for reducing the drain-to-source voltage across individual transistors have already been proposed. However, they present the disadvantage of increasing the complexity of the layout and of increasing the overall power consumption due to enhanced DC leakage current from gate to drain.

### SUMMARY OF THE INVENTION

It is therefore an object of the present invention to provide an improved high-voltage level shifter circuit in a simple configuration capable to avoid hot-carrier degradation and minimize leakage current, an integrated circuit including such a level shifter circuit, and a memory transistor comprising such an integrated circuit.

This object is achieved by a level shifter circuit as claimed in claim 1, an integrated circuit as claimed in claim 6, a memory transistor as claimed in claim 7, and a computing system as claimed in claim 8.

Therefore, a level shifter circuit is provided which comprises at least first and second transistors of a first conductivity type, which each comprises a source, a drain, a gate and a substrate. Each substrate is connected to a first voltage. A first input signal is inputted to the gate of the first transistor. A second input signal is inputted to the gate of the second transistor. The second input signal is complementary to the first input signal. The level shifter furthermore comprises third and fourth transistors of a second conductivity type each having a source, a drain, a gate and a substrate. Each source and respective substrate are connected together to a second voltage. The gate of the third transistor is connected to the drain of the second transistor. The gate of the fourth transistor is connected to the drain of the first transistor. The first and third transistors are connected in series. The second and fourth transistors are connected in series. The second transistor has its source at a voltage level higher than that of its substrate whenever the first input signal is at a high voltage level. The first transistor has its source at a voltage level higher than that of its substrate whenever the first input signal is at a low voltage level. The first transistor is turned ON when inputted by the high voltage level. The first transistor is turned OFF when inputted by the low voltage level. Accordingly, the drain-to-source voltage can be decreased, to avoid reaching the breakdown voltage of the transistors and minimizes hot-carrier degradation and the leakage of the load current flowing from the power supply voltage to the reference supply voltage.

According of an aspect of the invention the source of the second transistor is furthermore biased by the first input signal and the source of the first transistor is biased to the second input signal. Thereby, the complexity of the layout design is not increased.

According of an aspect of the invention the level shifter circuit further comprises fifth and sixth transistors of the second conductivity type, each having a source, a drain, a gate and a substrate. Each substrate is connected to the power supply. The gate of the fifth transistor is inputted by the first input signal. The gate of the sixth transistor is inputted by the second input signal. The drain of the first transistor and the fifth transistor are connected together. The drain of the second transistor and the sixth transistor are connected together. The source of the fifth transistor is connected to the drain of the second transistor. The source of the sixth transistor is connected to the drain of the third transistor. Thereby, hot-carrier degradation can also be minimized in a 6-transistor configuration.

The present invention extends to an integrated circuit including a level shifter circuit.

Preferably, the integrated circuit comprises a memory device including such a level shifter.

The present invention further extends to a computing system including such a memory device.

These and other features and advantages of the present invention will be apparent from the Figures as fully explained in the detailed description of embodiments of the invention.

### BRIEF DESCRIPTION OF THE DRAWINGS

The present invention will be now described based on preferred embodiments with reference to the accompanying drawings in which:

FIG. 1 shows a positive 4-transistor level shifter circuit according to the prior art;

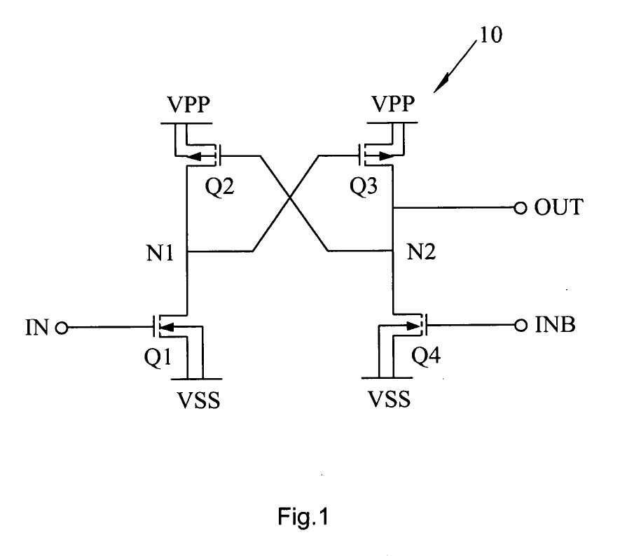

FIG. 2 shows a positive 4-transistor level shifter circuit according to a first embodiment of the present invention; and

FIG. 3 shows a positive 6-transistor level shifter circuit according to a second embodiment of the present invention.

### DETAILED DESCRIPTION OF EMBODIMENTS

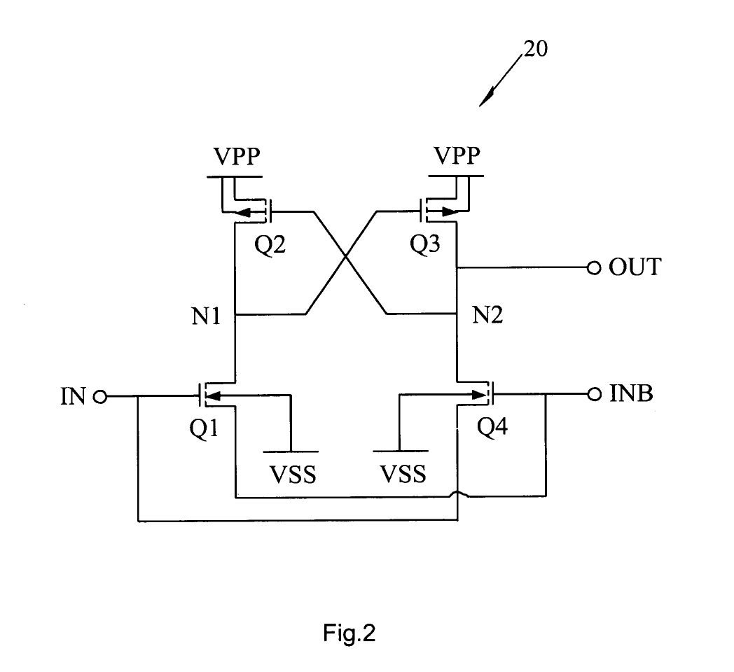

FIG. 2 is a positive 4-transistor level shifter circuit 20 according to a first embodiment of the present invention. Such level shifter circuit 20 comprises two N-type transistors Q1 and Q4 provided at the side of a reference voltage VSS, e.g. grounded voltage, and receiving, through the use of an inverter (not shown), complementary input signals from an input terminal IN and an input terminal INB, respectively. Both inputs being supplied by a row decoder for example. Two P-type transistors Q2 and Q3 are provided at the side of a power supply voltage, e.g. programming voltage VPP, generated by an on-chip charge pump for example. The cross-coupled transistors Q2 and Q3 constitute a flip-flop wherein the gate terminal of each transistor is connected to the drain terminal of the other at a series-connection node N2 of the transistors Q3 and Q4 and at a series-connection node N1 of the transistors Q1 and Q2, respectively. The substrate and source terminal of each of them is connected to the power supply voltage VPP. Each of the transistors Q1 and Q4 has its substrate connected to the reference voltage VSS, a source terminal connected to the input terminals INB and IN, respectively, and a drain terminal connected to the nodes N1 and N2, respectively. An output terminal OUT is connected to the node N2 for outputting an shifted-level output signal.

In a stationary state, when a signal is inputted at the input terminal IN with a high level, e.g. VCC, which is lower than the high level of the power supply voltage VPP, the transistor Q1 is turned ON and the transistor Q4 is turned OFF. In this case, the transistor Q3 is turned ON and the transistor Q2 is then turned OFF. The node N1 is pulled-down by the transistor Q1 at a low level provided by the reference voltage VSS, and the node N2 connected to the output terminal OUT is pulled-up by the transistor Q3 at a high level provided by the power supply voltage VPP. Thus, the level shifter circuit 20 outputs, from its output terminal OUT, a signal having a voltage VPP through the transistor Q3. The drain-to-source voltage across the transistor Q4 is substantially equal to the voltage difference between VPP and VCC, since the drain terminal is at the same voltage level as the output terminal OUT and the source terminal is at the same voltage level as the input terminal IN. Thus, the source biasing enables the source potential to be increased from VSS to VCC for reducing the drain-to-source voltage across the transistor Q4, which would be equal to the large voltage difference between VPP and VSS if the substrate and the source terminal were connected together. Such a reduction in the electric field across the drain and the source also allows to avoid hot-carrier degradation and dielectric breakdown of the transistor Q4, and to minimize the leakage of the load current susceptible to flow through the transistors Q3 and Q4.

In an alternative stationary state, when a signal is inputted at the input terminal IN with a low level, e.g. VSS which is chosen as the complementary voltage level to VCC, the transistor Q1 is turned OFF and the transistor Q4 is turned ON. In this case, the transistor Q2 is turned ON and the transistor Q3 is turned OFF. The node N1 is pulled-up by the transistor Q2 at a high level provided by the power supply voltage VPP, and the node N2 connected to the output terminal OUT is pulled-down by the transistor Q4 at a low level provided by the reference voltage VSS. Thus, the level shifter circuit 20 outputs, from its output terminal OUT, a signal having a voltage VSS through the transistor Q4. The drain-to-source voltage across the transistor Q1 is substantially equal to the voltage difference between VPP and VCC, since the drain terminal is at the same voltage level as the node N1 and the source terminal is at the same voltage level as the high level of the input terminal INB. Thus, the source-biasing enables the source potential to be increased from VSS to VCC for reducing the drain-to-source voltage across the transistor Q1, which would be equal to the large voltage difference between VPP and VSS if the substrate and the source terminal were connected together. Such a reduction in the electric field across the drain and the source also allows to avoid hot-carrier degradation and dielectric breakdown of the transistor Q1, and to minimize the leakage of the load current susceptible to flow through the transistors Q1 and Q2.

Furthermore, re-using on-chip elements, such as the input terminals IN and INB for allowing the source-biasing, does not increase the complexity of the layout.

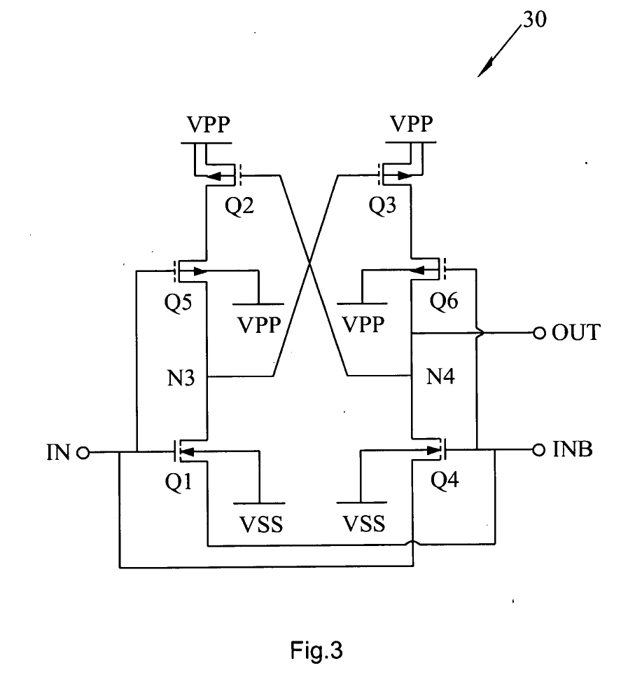

FIG. 3 is a positive 6-transistor level shifter circuit 30 according to a second embodiment of the present invention. Such level shifter circuit 30 comprises two N-type transistors Q1 and Q4 provided at the side of a reference voltage VSS, e.g. grounded voltage, and receiving, through the use of an inverter (not shown), complementary input signals from an input terminal IN and an input terminal INB, respectively. Both inputs are supplied by a row decoder for example. Two P-type transistors Q2 and Q3 are provided at the side of a power supply voltage, e.g. programming voltage VPP, generated by an on-chip charge pump for example, and two additional P-type transistors Q5 and Q6 coupled between the transistors Q1 and Q2 for Q5 and Q3 and Q4 for Q6. The gates of the transistors Q2 and Q3 are cross-connected to the series-connection nodes N4 of the transistors Q4 and Q6 and to the series-connection node N3 of the transistors Q1 and Q5, respectively. The substrate of the transistors Q2, Q3, Q5 and Q6 is connected to the power supply voltage VPP. The source terminal and the substrate of each transistor Q2 and Q3 are connected together. The gate terminal of each transistor Q5 and Q6 is connected to the input terminals IN and INB, respectively. Each of both transistors Q1 and Q4 are its drain terminal connected to the drain terminal of the transistors Q5 and Q6, respectively, and its substrate connected to the reference voltage VSS. The source terminal of the transistors Q1 and Q4 is connected to the input terminals INB and IN, respectively. An output terminal OUT is connected to the node N4 for outputting an shifted-level output signal.

In a stationary state, when a signal is inputted at the input terminal IN with a high level, e.g. VCC, which is lower than the high level of the power supply voltage VPP, the transistors Q1 and Q6 are turned ON, and the transistors Q4 and Q5 are turned OFF. In this case, the node N3 is pulled-down by the transistor Q1 at a low level provided by the reference voltage VSS, the transistor Q3 is turned ON, and the node N4 connected to the output terminal OUT is pulled-up by the transistors Q3 and Q6 at a high level provided by the power supply voltage VPP. The transistor Q2 is then turned OFF. Thus, the level shifter circuit 30 outputs, from its output terminal OUT, a signal having a voltage VPP through the transistors Q3 and Q6. The drain-to-source voltage across the transistor Q4 is substantially equal to the voltage difference between VPP and VCC, since the drain terminal is at the same voltage level as the output terminal OUT and the source terminal is at the same voltage level as the input terminal IN. Thus, the source biasing enables the source potential to be increased from VSS to VCC for reducing the drain-to-source voltage across the transistor Q4, which would be equal to the large voltage difference between VPP and VSS if the substrate and the source terminal were connected together. Such a reduction in the electric field across the drain and the source also allows to avoid hot-carrier degradation and dielectric breakdown of the transistor Q4, and to minimize the leakage of the load current susceptible to flow through the transistors Q3, Q6 and Q4.

In an alternative stationary state, when a signal is inputted at the input terminal IN with a low level, e.g. VSS which is chosen as the complementary voltage level to VCC, the transistors Q1 and Q6 are turned OFF, the transistors Q4 and Q5 are turned ON. In this case, the node N4 connected to the output terminal OUT is pulled-down by the transistor Q4 at a low level provided by the reference voltage VSS, the transistor Q2 is then turned ON such that the node N3 is pulled-up by the transistors Q2 and Q5 at a high level provided by the power supply voltage VPP. In turn, the transistor Q3 is turned OFF. Thus, the level shifter circuit 30 outputs, from its output terminal OUT, a signal having a voltage VSS through the transistor Q4. The drain-to-source voltage across the transistor Q1 is substantially equal to the voltage difference between VPP and VCC, since the drain terminal is at the same voltage level as the node N3 and the source terminal is at the same voltage level as the high level of the input terminal INB. Thus, the source-biasing enables the source potential to be increased from VSS to VCC for reducing the drain-to-source voltage across the transistor Q1, which would be equal to the large voltage difference between VPP and VSS if the substrate and the source terminal were connected together. Such a reduction in the electric field across the drain and the source also allows to avoid hot-carrier degradation and dielectric breakdown of the transistor Q1, and to minimize the leakage of the load current susceptible to flow through the transistors Q2, Q5 and Q1.

Furthermore, re-using on-chip elements, such as the input terminals IN and INB for allowing the source-biasing, does not increase the complexity of the layout.

The level shifter circuit 20, 30 operating in accordance with the principles of the present invention, may be used in all memory devices requiring high voltage, such as flash EEPROM, EEPROM, OTP or MTP nonvolatile memory, and more generally in all systems using high-voltage level shifter circuits.

Moreover, the present invention is not limited to the positive level shifter circuits such as described in the aforementioned examples for converting an input signal having a positive voltage to a shifted signal having a higher positive voltage. The present invention is also applicable to negative level shifter circuits for converting a signal having a negative voltage to a shifted signal having a higher negative voltage, by replacing N-type transistors and P-type transistors in positive level shifter circuits with P-type transistors and N-type transistors, respectively.

In summary, a level shifter circuit 20 for devices requiring high voltage, such as nonvolatile memories, has been described. In the circuit configuration, the drain-to-source voltage across the NMOS transistors Q1, Q4 can be substantially equal to the power supply voltage VPP according to the input voltage level at the complementary input terminals IN, INB. For alleviating such a voltage stress, the source potential of each NMOS transistor is increased according to the input voltage level. Thus, the source of the transistor at the OUT side is biased by the input signal at the input terminal IN and the source of the transistor at the IN side is biased by the complementary input signal at the corresponding terminal INB. Hot-carrier degradation and leakage of the load current flowing through from the power supply voltage VPP to the reference voltage VSS can be then reduced.

Finally but yet importantly, it is noted that the term “comprises” or “comprising” when used in the specification including the claims is intended to specify the presence of stated features, means, steps or components, but does not exclude the presence or addition of one or more other features, means, steps, components or group thereof. Further, the word “a” or “an” preceding an element in a claim does not exclude the presence of a plurality of such elements. Moreover, any reference sign does not limit the scope of the claims.

1. A level shifter circuit comprising at least:
first and second transistors of a first conductivity type, each having a source, a drain, a gate and a substrate, each substrate being connected to a first voltage,
wherein a first input signal is inputted to said gate of said first transistor,
wherein a second input signal is inputted to said gate of said second transistor,
wherein said second input signal is complementary to said first input signal;
third and fourth transistors of a second conductivity type, each having a source, a drain, a gate and a substrate, each source and respective substrate being connected together to a power supply,
wherein said gate of said third transistor is connected to said drain of said second transistor,
wherein said gate of said fourth transistor is connected to said drain of said first transistor,
wherein said first and third transistors are connected in series, wherein said second and fourth transistors are connected in series;
wherein said second transistor has its source at a voltage level higher than that of its substrate whenever said first input signal is at a high voltage level, and said first transistor has its source at a voltage level higher than that of its substrate whenever said first input signal is at a low voltage level,
wherein said first transistor being turned ON when inputted by said high voltage level,
wherein said first transistor is turned OFF when inputted by said low voltage level.

2. A level shifter circuit according to claim 1, wherein
said source of said second transistor is biased by said first input signal and said source of said first transistor is biased by said second input signal.

3. A level shifter circuit according to claim 1, further comprising:
fifth and sixth transistors of said second conductivity type, each having a source, a drain, a gate and a substrate, each substrate being connected to said power supply,
wherein said first input signal is inputted to said gate of said fifth transistor,
wherein said second input signal is inputted to said gate of said sixth transistor,
wherein said drain of said first transistor and said fifth transistor are connected together,
wherein said drain of said second transistor and said sixth transistor are connected together,
wherein said source of said fifth transistor is connected to said drain of said second transistor,
wherein said source of said sixth transistor is connected to said drain of said third transistor.

4. A level shifter circuit according to claim 1 wherein the first voltage corresponds to a reference supply voltage.

5. A level shifter circuit according to claim 1, wherein the second voltage corresponds to a power supply voltage.

6. An integrated circuit comprising a level shifter circuit according to claim 1.

7. A memory device comprising a level shifter circuit according to claim 1.

8. A computing system comprising an integrated circuit according to claim 6.
